(19) United States
(12) Patent Application Publication
(10) Pub. No.: US 2011/0228105 A1
(43) Pub. Date: Sep. 22, 2011

(54) DATA TRANSFER DEVICE AND ELECTRONIC CAMERA

(75) Inventor: Daiki Ito, Tokyo (JP)

(73) Assignee: NIKON CORPORATION, Tokyo (JP)

(21) Appl. No.: 13/002,555

(22) PCT Filed: Jul. 16, 2009
(86) PCT No.: PCT/JP2009/003357

§ 371 Date: Mar. 31, 2011

(30) Foreign Application Priority Data
Jul. 18, 2008 (JP) 2008-187400

(51) Int. Cl. H04N 5/225; H03L 7/00

(52) U.S. Cl. 348/207.1; 327/161; 348/E05.024

(57) ABSTRACT

A reception section receiving a reference signal and a data signal of data which is to be transferred, a holding section holding a test signal of test data received prior to the data and the reference signal, a calculation section calculating a delay amount which occurs between the reception of the data signal and the reception of the reference signal by using the test signal and the reference signal held by the holding section, and a delay section relatively delaying the data signal from the reference signal based on the delay amount.

### TECHNICAL FIELD

The present application relates to a data transfer apparatus suitable for high-speed transfer of digital data between electronic devices or between semiconductor elements, and to a peripheral technique thereof.

### BACKGROUND ART

A recent increase in pixels and so on of an image sensor are creating a demand for higher speed transfer of digital data. In a conventional design of an electronic device aiming at high-speed transfer, impedance control and equal-length wiring of transfer lines, or selection of materials of a printed circuit board and so on are performed, followed by simulations of a signal waveform and so on.

However, when the transfer speed becomes on the order around gigahertz, only the measures such as the equal length wiring have a limit, and influences of noise, jitter (fluctuation of delay time of data signals), and so on make stable high-speed transmission difficult. Therefore, for example, a reference document 1 and a reference document 2 disclose data transfer apparatuses each using a clock signal as a reference signal in parallel data transfer to thereby adjust variation among data signals due to their delays caused by the transfer.

Prior Art Documents

Patent Documents

### Patent Document 1: Japanese Unexamined Patent Application Publication No. 2004-171254

Patent Document 2: Japanese Unexamined Patent Application Publication No. H11-112483

### DISCLOSURE OF THE INVENTION

### Problems to be Solved by the Invention

However, in the reference document 1 being a conventional art, since a signal of test data for adjustment is kept output until the completion of the adjustment of a delay amount, the data transfer is not allowed during this period, which necessarily becomes a waiting time.

Further, in the reference document 2, in the adjustment of the delay amount, an optimum delay amount is calculated based on the comparison between test data before the transfer and that after the transfer, which involves a problem that a mounted circuit becomes complicated and large-scaled.

In consideration of the aforesaid problem that the conventional art has, it is a proposition of the present invention to provide an art capable of high-accuracy and high-speed reduction of a delay of a data signal from a clock signal.

### Means for Solving the Problems

In order to solve the aforesaid problems, a data transfer apparatus of the present embodiment includes a reception section receiving a reference signal and a data signal of data that which to be transferred, a holding section holding a test signal of test data received prior to the data and the reference signal, a calculation section calculating a delay amount which occurs between the reception of the data signal and the reception of the reference signal by using the test signal and the reference signal held by the holding section, and a delay section relatively delaying the data signal from the reference signal based on the delay amount.

A data transfer apparatus of the present embodiment includes a transmission section synchronizing a data signal of data with a reference signal and transmitting the data signal together with the reference signal; a reception section receiving the reference signal and the data signal; a plurality of transfer lines through which the reference signal and the data signal are transferred respectively from the transmission section to the reception section; and a control section controlling operations of the transmission section and the reception section in which the transmission section includes a storage section storing test data to be used to obtain a delay amount between the reference signal and the data signal which occurs due to the transfer to the reception section and the reception section includes a holding section holding a test signal of the test data received from the storage section prior to the data and the reference signal, a calculation section calculating the delay amount between the data signal and the reference signal which occurs due to the transfer by using the test signal and the reference signal held by the holding section, and a delay section relatively delaying the data signal from the reference signal based on the delay amount.

The control section may further include a temperature measurement section measuring a temperature of the data transfer apparatus; and when the temperature measured by the temperature measurement section becomes a predetermined value, the control section may cause the storage section to output the test signal of the test data, cause the calculation section to calculate the delay amount by using the test signal and the reference signal newly held by the holding section, and cause the delay section to delay the data signal relatively from the reference signal by using the delay amount being newly found.

The calculation section may calculate the delay amount while relatively shifting the test signal and the reference signal from each other.

The calculation section may obtain a product of the test signal and the reference signal while relatively shifting the test signal and the reference signal from each other and calculate the delay amount based on a change in a value of the product.

The holding section may hold the test signal and the reference signal in a predetermined time interval.

The test signal may be a binary data row whose value alternately changes at a same cycle as a cycle of the reference signal.

An electronic camera of the present embodiment includes an imaging section capturing an image of a subject to generate a picture, and the data transfer apparatus of the present embodiment.

### Effect of the Invention

According to the present invention, high-accuracy and high-speed reduction of a delay of a data signal from a clock signal is enabled.

### BRIEF DESCRIPTION OF THE DRAWINGS

FIG. 1 is a schematic diagram showing an example of the structure of a data transfer apparatus 100 according to one embodiment of the present invention.

FIG. 2 is a schematic diagram showing an example of the structure of a delay section 31 according to the embodiment of the present invention.

FIG. 3 is a flowchart showing the procedure of delay adjustment of the delay section 31 according to the embodiment of the present invention.

FIG. 4 is a timing chart showing the procedure of the delay adjustment of the delay section 31 according to the embodiment of the present invention.

### BEST MODE FOR CARRYING OUT THE INVENTION

### Description of Embodiment

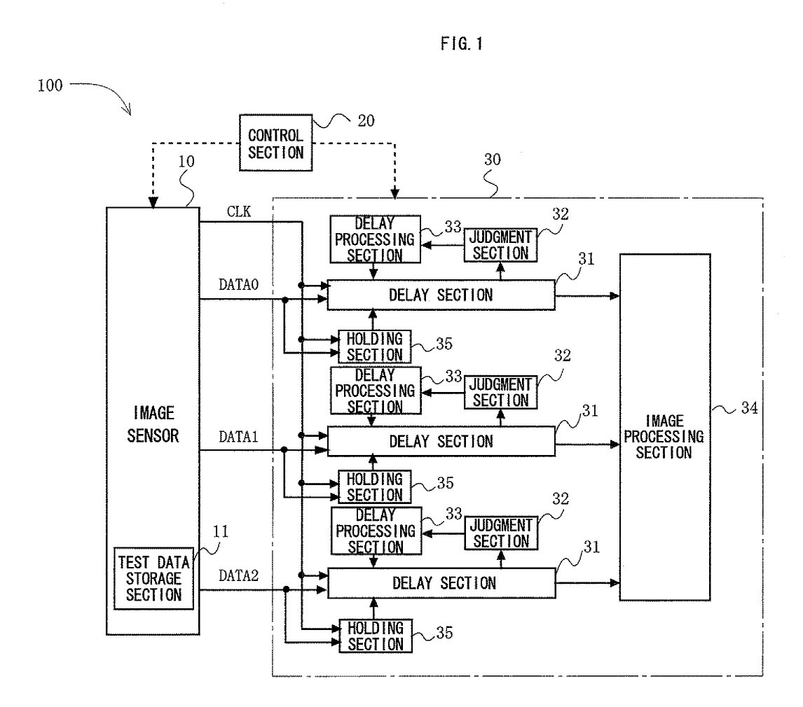

FIG. 1 is a schematic diagram showing an example of the structure of a data transfer apparatus 100 according to an embodiment of the present invention. FIG. 1 shows the structure example where an image sensor 10 of an electronic camera is a transmission section and a signal processing circuit 30 of the electronic camera is a reception section, and they operate based on a control section 20.

The image sensor 10 of this embodiment has a light-receiving surface on which a plurality of imaging pixels are two-dimensionally arranged, and outputs image signals of a subject image that an imaging optical system (not shown) forms on the light-receiving surface. Further, the image sensor 10 has an on-chip A/D converter (not shown), and digital data signals are output from output terminals of the image sensor 10.

Here, one-side ends of three data signal lines DATA0-DATA2 serially transferring data signals of an image and one end of a clock signal line CLK outputting a clock signal serving as a reference signal are connected to the image sensor 10 of this embodiment. The other ends of the aforesaid signal lines are connected to the signal processing circuit 30, and the data signals of the image are serially transferred between the image sensor 10 and the signal processing circuit 30 through the three channels. Further, the image sensor 10 has a test data storage section 11 storing later-described test data for the three data signal lines DATA0-DATA2 and also has a function of outputting the test data.

When a user turns on the electronic camera, the control section 20 reads a control program stored in advance in a mounted memory (not shown), and based on the control program, the control section 20 commands the image sensor 10 to capture an image of a subject, and controls the data transfer, image processing, and so on of the captured image.

By means of a mode signal, the control section 20 instructs the image sensor 10 and the signal processing section 30 whether to perform normal transfer of image data (the mode signal is Low (0)) or whether to make delay adjustment (the mode signal is High (1)). As the control section 20, an ordinary CPU of a computer is usable.

The signal processing circuit 30 is a digital front-end circuit applying various kinds of image processing to digital data signals of an image input from the image sensor 10. The signal processing circuit 30 has a delay section 31, a judgment section 32, a delay processing section 33, and a holding section 35 in each of the data signal lines DATA0-DATA2. Note that only a major part of the data transfer apparatus is shown in FIG. 1. For example, in FIG. 1, an enforcement section keeping the whole operation of the signal processing circuit 30 under surveillance, a data discrimination section decoding the retrieved data signals of the image, and so on are omitted.

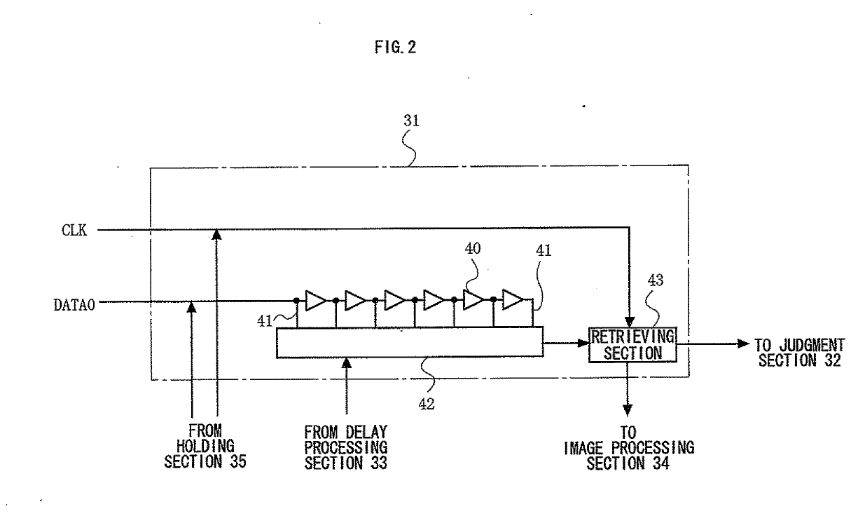

The delay sections 31, which are connected to the data signal lines DATA0-DATA2 and the clock signal line CLK, are circuits adjusting delays of data signals of an image to retrieve image data. FIG. 2 is a schematic diagram showing an example of the structure of the delay section 31. The delay section 31 includes six delay elements (inverters or the like) connected in series; a plurality of paths 41 connected to outputs of the respective delay elements 40; a selector 42 selecting one of the paths 41 according to an instruction of the delay processing section 33; and a retrieving section 43 retrieving a data signal of an image having undergone the delay adjustment, in synchronization with the clock signal. A delay amount of the data signal from each of the data signal lines DATA0-DATA2 is adjusted according to the path 41 selected by the selector 42 and the resultant data signal is output to the retrieving section 43.

Here, the retrieving section 43 retrieves a value that the data signal has, in synchronization with a rising timing or a falling timing of the clock signal. Then, at the time of the normal retrieving of the data signal of the image, the retrieving section 43 outputs the data signal to an image processing section 34, and at the time of the delay adjustment, it outputs, to the judgment section 32, a flag signal having a value equal to a product (AND circuit) of the clock signal and the data signal. In this embodiment, it is assumed that the retrieving section 43 retrieves the value of the data signal at a rising timing of the clock signal in a later-described operation example.

Based on an output pattern of the flag signal from the retrieving section 43 at the time of the delay adjustment, the judgment section 32 judges, for each of the data signal lines DATA0-DATA2, whether the data signal coincides with the clock signal.

The delay processing section 33 is a processor controlling the delay amount of the delay section 31. Based on an output of the judgment section 32, the delay processing section 33 decides the delay amount of the delay section 31 and instructs the selector 42 to set the delay amount.

The image processing section 34 is an ASIC or the like applying various kinds of image processing (defective pixel correction, color interpolation, gradation correction, white balance correction, edge enhancement, and so on) to the digital image signals.

At the time of the delay adjustment, according to an instruction of the delay processing section 33, the holding section 35 holds the clock signal and a test signal of the test data which are output from the image sensor 10, and outputs the held signals to the delay section 31 for the delay adjustment. As the holding section 35, a storage device such as a buffer memory or a line memory can be appropriately selected and used.

Next, the adjustment of delay between the data signals and the clock signal in the data transfer apparatus 100 of this embodiment at the time of the transfer of the data signals of the image from the image sensor 10 to the signal processing circuit 30 will be described. The delay sections 31, the judgment sections 32, and the delay processing sections 33 of the data signal lines DATA0-DATA2 have common structures. Therefore, only the delay adjustment in the data signal line DATA0 will be described below for simplification, but actually, the same processing progresses in parallel also in the other data signal lines DATA1 and DATA2.

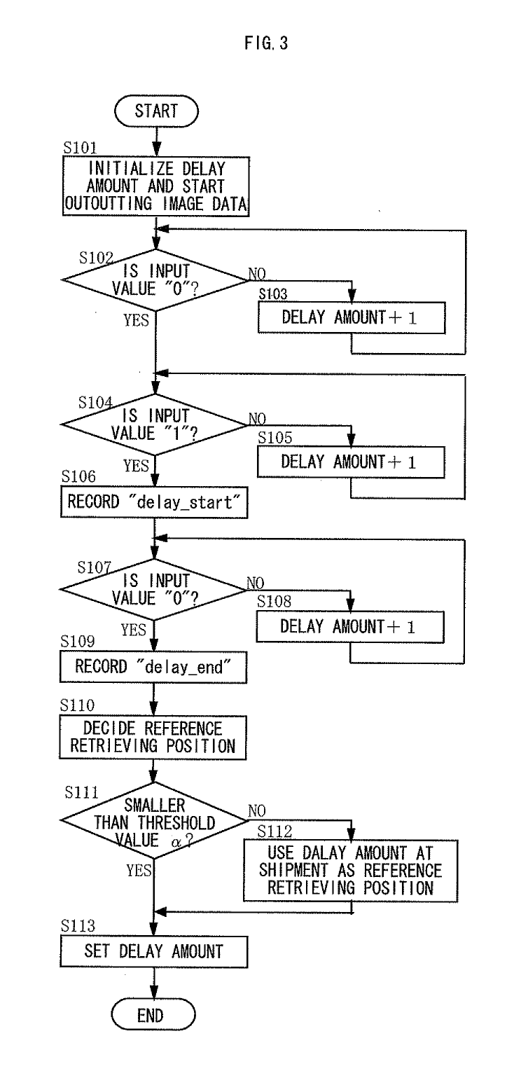

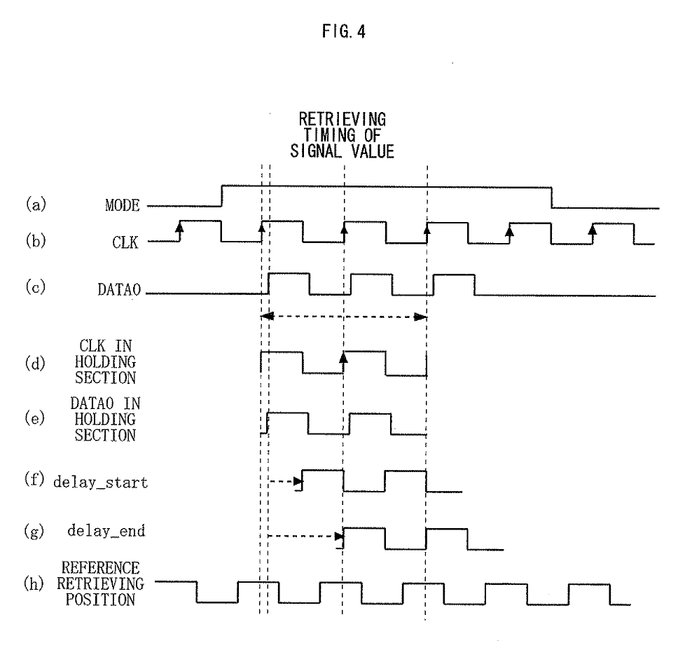

The operation of the delay adjustment will be described based on the flowchart in FIG. 3 and the timing chart in FIG. 4.

In this embodiment, this processing is executed at a timing immediately before image data is transferred, for instance. The test data is made up of a binary data row in which “0” and “1” are repeated at the same cycle as that of the clock signal. Further, an internal memory or the like of the delay processing section 33 stores in advance a delay amount found at the time of the manufacture, which amount is used when the delay adjustment is judged as a failure because the delay amount found by the delay adjustment becomes equal to or larger than a threshold value α.

Step S101: The control section 20 initializes the delay amount of the delay section 31.

Then, the control section 20 instructs the image sensor 10 to start outputting the test data (the mode signal changes from Low (0) to High (1) (FIG. 4(a)). Consequently, from the image sensor 10, a three-pulse test signal is output to each of the data signal lines DATA0-DATA2, in synchronization with the clock signal. In addition to instructing the image sensor 10 to output the test data, the control section 20 also instructs the delay processing section 33 to make the delay adjustment of the delay section 31, by changing the mode signal from Low to High. Consequently, the clock signal and the test data of the data signal line DATA0 are held by the holding section 35 (FIG. 4 (b) (c)). The delay processing section 33 clips the clock signal and the test signal of the test data, corresponding to two periods from a position of a falling edge of the clock signal (FIG. 4 (d) (e)). The delay processing section 33 causes the holding section 35 to output the clipped clock signal and the test signal to the clock signal line CLK and the data signal line DATA0 of the delay section 31.

Step S102: The delay processing section 33 causes the judgment section 32 to judge whether the flag signal output from the retrieving section 43 at a rising timing of the clock signal has “0” or not. When the flag signal has “0”, a shift to Step S104 (YES side) takes place. On the other hand, when the flag signal does not have “0”, a shift to Step S103 (NO side) takes place.

Step S103: Based on the judgment of the judgment section 32, the delay processing section 33 commands the selector 42 to increase the delay amount of the delay section 31 (delay stage number of the delay circuit) by “1” to delay a phase. The delay processing section 33 causes the holding section 35 to output again the clock signal and the test signal clipped at Step S101. Thereafter, the delay processing section 33 returns to Step S102. The loop from the NO side at Step S102 to Step S103 corresponds to an operation of once shifting a retrieving position of the data signal until the flag signal has the “0” value in order to search for a rising position of a signal waveform in the use of the test data.

Step S104: The delay processing section 33 causes the judgment section 32 to judge whether the flag signal output from the retrieving section 43 at the rising timing of the clock signal has “1”. When the flag signal has “1”, a shift to Step S106 (YES side) takes place. On the other hand, when the flag signal does not have “1”, a shift to Step S105 (NO side) takes place.

Step S105: Based on the judgment of the judgment section 32, the delay processing section 33 instructs the selector 42 to increase the delay amount of the delay section 31 by “1” to delay the phase. The delay processing section 33 causes the holding section 35 to output again the clock signal and the test signal which are clipped at Step S101. Thereafter, the delay processing section 33 returns to Step S104. The loop from the NO side at Step S104 to Step S105 corresponds to an operation of shifting the retrieving position of the data signal to a rising position of the signal waveform in the use of the test data.

Step S106: The delay processing section 33 temporarily holds the current delay amount of the delay section 31 as “delay_start”. The delay amount “delay_start” held at Step S106 corresponds to the rising position of the signal waveform in the use of the test data (FIG. 4 (f)).

Step S107: The delay processing section 33 causes the judgment section 32 to judge whether the flag signal output from the retrieving section 43 at the rising timing of the clock signal has “0”, When the flag signal has “0”, a shift to Step S109 (YES side) takes place. On the other hand, when the flag signal does not have “0”, a shift to Step S108 (NO side) takes place.

Step S108: Based on the judgment of the judgment section 32, the delay processing section 33 instructs the selector 42 to increase the delay amount of the delay section 31 by “1” to delay the phase. The delay processing section 33 causes the holding section 35 to output again the clock signal and the test signal which are clopped at Step S101. Thereafter, the delay processing section 33 returns to Step S107. The loop from the NO side at Step S107 to Step S108 corresponds to an operation of shifting the retrieving position of the data signal to a falling position of the signal waveform in the use of the test data.

Step S109: The delay processing section 33 temporarily holds the current delay amount of the delay section 31 as “delay_end”. The delay amount “delay_end” recorded at Step S109 corresponds to the falling position of the signal waveform in the use of the test data (FIG. 4 (g)).

Step S110: The delay processing section 33 decides a delay amount (a reference retrieving position of the data signal) of the delay section 31 for data communication, by using the delay amount “delay_start” obtained at Step S106 and the delay amount “delay_end” obtained at Step S109. In this embodiment, the delay processing section 33 calculates the reference retrieving position of the data signal by the following expression (1).

Reference retrieving position=(delay_start+delay_end)/2 (1)

Step S111: The delay processing section 33 judges whether the reference retrieving position found at Step S110 is smaller than the threshold value α or not. When the reference retrieving position is smaller than α, the delay processing section 33 determines that the delay adjustment is made correctly and shifts to Step S113 (YES side). On the other hand, when the reference retrieving position is larger than the threshold value α, the delay processing section 33 determines that the delay adjustment is not made correctly to shift to Step S112 (NO side).

Step S112: The delay processing section 33 decides the delay amount found at the time of the manufacture as the reference retrieving position.

Step S113: The delay processing section 33 informs the selector 42 of the delay stage number of the delay element 40 corresponding to the reference retrieving position found at Step S110 or the reference retrieving position decided at Step S112. The delay processing section 33 outputs, to the enforcement section (not shown) of the signal processing circuit 30, a flag signal informing that the delay adjustment of the delay section 31 of the data signal line DATA0 has been finished.

The operations from Step S101 to Step S113 are performed in parallel for the delay adjustment of the delay sections 31 of the other data signal lines DATA1 and DATA2. When the delay adjustment of each of the delay sections 31 is finished, each of the delay processing sections 33 outputs the end flag signal to the enforcement section. When receiving the end flags from all the delay processing sections 33, the enforcement section outputs an adjustment completion flag to the control section 20 and also commands the delay processing sections 33 to maintain the current delay amounts, and then the delay adjustment operation is finished.

Thereafter, when receiving the adjustment completion flag, the control section 20 changes the mode signal from High to Low to command the image sensor 10 to transfer the image data. The image sensor 10 outputs the data signals of the image to the data signal lines DATA0 to DATA2 in synchronization with the clock signal. When the signal processing circuit 30 receives the data signals, the data signals undergo the delay adjustment in the delay sections 31 of the data signal lines DATA0-DATA2 (FIG. 4 (h)), and the image data are sent to the image processing section 34.

As described above, in this embodiment, it is possible to make the delay adjustment of the delay sections 31 with high accuracy and at high speed, by causing the holding section 35 to temporarily hold the clock signal and the test signal of the test data synchronized with the clock signal and to output these signals for the delay adjustment.

Further, since the delay adjustment is independently made for each of the delay sections 31 of the data signal lines DATA0-DATA2, it is possible to avoid equal-length wiring design of the data transfer apparatus 100 of a serial type, which greatly improves a degree of freedom in the layout of elements and wiring in circuit design.

Further, in this embodiment, since the reference retrieving position found at Step S110 every time image data is transferred is decided based on actual measurement values, an error due to variation in wiring length and elements or due to an environmental change is also absorbed, which can improve reliability of the data transfer apparatus 100.

<Supplementary Matters of Embodiment>in this embodiment, the example of the data transfer between the image sensor 10 and the signal processing circuit 30 in the camera is described, but the data transfer apparatus of the present invention is also applicable to data transfer between other elements in the camera. For example, the image sensor 10 may be replaced by an analog front-end (AFE) receiving image data from the image sensor 10. Further, the data transfer apparatus according to the present invention is also applicable to a digital processing circuit built in any other electronic device. Further, the data transfer apparatus of the present invention is also applicable to wired data transfer between electronic devices independent of each other. Further, the data transfer apparatus of the present invention is applicable to transfer of not only a digital signal but also an analog signal since it is possible to prevent data signals from being influenced by noise, jitter, or the like during the transfer.

In this embodiment, the transfer mode of image data is the serial mode, but it should be noted that the data transfer apparatus according to the present invention is also applicable to a parallel mode.

In this embodiment, the test signal of the test data is made up of three pulses, but the present invention is not limited to this, and the number of pulses may be decided according to required delay accuracy, processing power of the data transfer apparatus, and the like.

In this embodiment, since the holding section 35 deals with high-speed signals and thus its circuit is expected to become large, an amount of the held data is preferably smaller, and therefore, at the time of the delay adjustment, the length of the data clipped from the clock signal and the test signal held by the holding section 35 for the delay adjustment is set to a length corresponding to two periods, but the present invention is not limited to this, and the length may be appropriately decided according to required delay accuracy, processing power of the data transfer apparatus, and the like.

In this embodiment, the retrieving section 43 retrieves the value of the data signal at a rising timing of the clock signal, but may retrieve the value of the data signal at a falling timing of the clock signal.

In this embodiment, the number of the delay elements 40 of each of the delay sections 31 is six, but the present invention is not limited to this, and the number of the delay elements 30 may be appropriately decided according to a delay amount of the single delay element 30, and the size of a range by which the phase of the test data is delayed from the clock signal.

In this embodiment, the delay processing sections 33 are disposed for the respective delay sections 31 of the data signal lines DATA0-DATA2, but the present invention is not limited to this. For example, the single delay processing section 33 may make the delay adjustment of all the delay sections 31. This enables a reduction in circuit scale.

In this embodiment, the reference retrieving position is found by the expression (1), but the present invention is not limited to this, and the reference retrieving position can be found by using a different expression.

In this embodiment, the data signal is delayed from the clock signal for the delay adjustment, but the present invention is not limited to this, and the clock signal may be delayed from the test signal for the delay adjustment.

In this embodiment, the delay adjustment of the delay section 31 is made every time image data is transferred, but the present invention is not limited to this. For example, the delay adjustment may be made every time a predetermined time passes or may be made every time a large sequence operation is performed. Another alternative may be that the control section 20 has a temperature sensor, and when a temperature measured by the temperature sensor or its change amount becomes larger than a predetermined value, the control section 20 gives a command for the delay adjustment of the delay section 31. Consequently, a delay error due to a change in a photographing environment or the like can be absorbed, which can further improve reliability of the data transfer apparatus 100. However, it is suitable that a data table or the like of delay amounts for respective temperatures found at the time of the manufacture are stored in advance in an internal memory or the like of the delay processing section 33.

In this embodiment, the operations from Step S101 to Step S113 of the delay adjustment of each of the delay sections 31 are performed only once, but the present invention is not limited to this. For example, the delay processing section 33 may perform the operations from Step S101 to Step S110 a plurality of times for each of the delay sections 31, calculate an average value of the plural found reference retrieving positions, and set the average value as a delay amount in the selector 42 at Step S113. Alternatively, the control section 20 instructs the image sensor 10 a plurality of times to output the test data and also instructs the delay processing section 33 to make the delay adjustment of the delay section 31 at Step S101 to Step S113, every time the test signal is received. Then, the delay processing section 33 may calculate an average value of the reference retrieving positions found by using the respective test data, and set, in the selector 42, the average value as a delay amount of the delay section 31. Consequently, accuracy of the delay adjustment can be enhanced. However, when the average value is used, jitter/skew of the data signal needs to be taken into consideration, and it is suitable that the delay processing section 33 holds, in advance, table data of an amount of the jitter/skew at each temperature, and the amount is subtracted from the average value.

In this embodiment, the example of the data transfer apparatus performing the serial transfer in three channels is described, but the number of the channels of the data transfer apparatus of the present invention is not limited to this, and the present invention is of course applicable also to a data transfer apparatus performing serial transfer in one channel or two or more plural channels.

The present invention can be embodied in other various forms without departing from its spirit or its major features. Therefore, the above-described embodiment is only an example in all respects and should not be interpreted as restrictive. The present invention becomes apparent by the claims, and the text of the specification in no way restricts the present invention. Further, all modifications and changes falling under the equivalent scope of the claims are included in the scope of the present invention.

### EXPLANATION OF REFERENCES

CLK clock signal line, DATA0-DATA2 data signal line, 10 image sensor, 11 test data storage section, 20 control section, 30 signal processing circuit, 31 delay section, 32 judgment section, 33 delay processing section, 34 image processing section, 35 holding section, 40 image sensor, 41 path, 42 selector, 43 retrieving section, 100 data transfer apparatus.

1. A data transfer apparatus comprising:
a reception section receiving a reference signal and a data signal of data which is to be transferred;
a holding section holding a test signal of test data and the reference signal, the test data being received prior to the data;
a calculation section calculating a delay amount which occurs between the reception of the data signal and the reception of the reference signal by using the test signal and the reference signal held by the holding section; and
a delay section relatively delaying the data signal from the reference signal based on the delay amount.

2. A data transfer apparatus comprising:
a transmission section synchronizing a data signal of data with a reference signal and transmitting the data signal together with the reference signal;
a reception section receiving the reference signal and the data signal;
a plurality of transfer lines through which the reference signal and the data signal are transferred respectively from the transmission section to the reception section; and
a control section controlling operations of the transmission section and the reception section, wherein:
the transmission section includes
a storage section storing test data to be used to obtain a delay amount between the reference signal and the data signal which occurs due to the transfer to the reception section; and
the reception section includes:
a holding section holding a test signal of the test data received from the storage section prior to the data and the reference signal;
a calculation section calculating the delay amount between the data signal and the reference signal which occurs due to the transfer by using the test signal and the reference signal held by the holding section; and
a delay section relatively delaying the data signal from the reference signal based on the delay amount.

3. The data transfer apparatus according to claim 2, wherein:
the control section further includes a temperature measurement section measuring a temperature of the data transfer apparatus; and
when the temperature measured by the temperature measurement section becomes a predetermined value, the control section causes the storage section to output the test signal of the test data, causes the calculation section to calculate the delay amount by using the test signal and the reference signal newly held by the holding section, and causes the delay section to delay the data signal relatively from the reference signal by using the delay amount being newly found.

4. The data transfer apparatus according to claim 1, wherein
the calculation section calculates the delay amount while relatively shifting the test signal and the reference signal from each other.

5. The data transfer apparatus according to claim 1, wherein
the calculation section obtains a product of the test signal and the reference signal while relatively shifting the test signal and the reference signal from each other and calculates the delay amount based on a change in a value of the product.

6. The data transfer apparatus according to claim 1, wherein
the holding section holds the test signal and the reference signal in a predetermined time interval.

7. The data transfer apparatus according to claim 1, wherein
the test signal is a binary data row whose value alternately changes at a same cycle as a cycle of the reference signal.

8. An electronic camera comprising:
an imaging section capturing an image of a subject to generate a picture; and
the data transfer apparatus according to claim 1.
